(19) United States
(12) Patent Application Publication
(10) Pub. No.: US 2026/0136563 A1
(43) Pub. Date: May 14, 2026

(54) Method FOR Manufacturing Semiconductor Interconnect Structure

(71) Applicant: SJ Semiconductor(Jiangyin) Corporation, Jiangyin (CN)

(72) Inventors: Yenheng CHEN, Jiangyin (CN); Chengchung LIN, Jiangyin (CN)

(73) Assignee: SJ Semiconductor(Jiangyin) Corporation, Jiangyin, JS (CN)

(21) Appl. No.: 19/121,792

(22) PCT Filed: Jun. 1, 2023
(86) PCT No.: PCT/CN2023/097812

§ 371 Date: Apr. 16, 2025

(30) Foreign Application Priority Data
Oct. 17, 2022 (CN) 2022112643213

(51) Int. Cl. H10B 80/00; H10W 90/00; H10W 90/10; H10W 90/20

(52) U.S. Cl. CPC H10B 80/00; H10W 90/10; H10W 90/288; H10W 90/297; H10W 90/722; H10W 90/724

(57) ABSTRACT

A method for making a semiconductor interconnect structure includes forming a first metal interconnect layer on the surface of a first semiconductor substrate, and a second metal interconnect layer on the surface of a second semiconductor substrate; and forming bonding structures at the edges of at least one of the surfaces of the two metal interconnect layers, bonding the two metal interconnect layers together by the bonding structures, leaving a connection space between the metal surfaces of the two interconnect layers, and applying another metal interconnect filler at the connection space by an electroless chemical plating technique to connect the metal surfaces of the two metal interconnect layers after the bonding. These steps can be repeated to form a stack of N-layer interconnection structures. This process achieves good electrical interconnect and easily meets the flatness requirement for the metal surfaces for high-density integrated circuit packaging at low cost.

### FIELD OF THE INVENTION

The present invention relates to the field of semiconductors, and in particular, to a method for manufacturing a semiconductor interconnect structure.

### BACKGROUND OF THE INVENTION

In the early development of integrated circuits, the main driving force of technological progress was by means of size scaling. Moore's law refers to that the number of transistors that can be accommodated on an integrated circuit has increased by a factor of approximately every 18 months to 24 months. Thus, the performance of the processors has been doubled every two years, while the price has dropped to half of the previous.

When the spatial critical dimension variation of the chips simply depends on the size of the micro-scaling, the circuits with different functions are integrated together, and improving the chip performance by two-dimensional shrinking is achieved by means of size scaling and design optimization. At present, the design idea of advanced packaging technology Chiplet (which can be understood as a “core particle”) starts to decompose the SOC into a GPU, a CPU, an IO chip, etc. which then get integrated in a packaging structure through the SIP technology, which is an excellent technology and able to customize a product according to the unique requirements from specific customers. However, the Chiplet technology requires a high interconnect density, so it is desirable to consider how to maintain a highly efficient manufacturing process when assembling the chips together. Although the conventional hybrid bonding technology has the advantages of high current load capacity, small spacing, and good thermal performance, this process application has great limitation because of high manufacturing cost and stringent interface flatness requirement.

Therefore, it is necessary to provide a new metal interconnection in a semiconductor structure and a method for manufacturing it.

### SUMMARY OF THE INVENTION

The present invention provides a method for manufacturing a semiconductor interconnection structure.

The method for manufacturing the semiconductor interconnection structure includes the following steps:
providing a first semiconductor substrate, the first semiconductor substrate comprising a first connector;
forming a first metal interconnection layer on a surface of the first semiconductor substrate, where the first metal interconnection layer includes a first dielectric layer and a first metal member, and the first metal member penetrates through the first dielectric layer and is electrically connected to the first connection member;
providing a second semiconductor substrate, the second semiconductor substrate comprising a second connector;
forming a second metal interconnection layer on a surface of the second semiconductor substrate, where the second metal interconnection layer includes a second dielectric layer and a second metal member, and the second metal member penetrates through the second dielectric layer and is electrically connected to the second connection member; and
forming a bonding member on an edge of the surface of at least one of the first metal interconnection layer and the second metal interconnection layer;
bonding the first metal interconnection layer and the second metal interconnection layer based on the bonding member, and a connection space is left between to the first metal member and the second metal member after bonding;
forming a metal interconnect at the connection space by electroless plating to connect the first metal member and the second metal member; and
forming a bottom filling layer, filling a gap between the first metal interconnection layer and the second metal interconnection layer.

Optionally, after the bonding, a center line of the first metal member aligns with a center line of the second metal member.

Optionally, after the bonding, a perpendicular distance between the first metal interconnection layer and the second metal interconnection layer has a range of 10 μm-50 μm.

Optionally, the bonding member includes a thermosetting bonding member or a UV bonding member.

Optionally, the step of forming the first metal interconnection layer includes forming a first metal member on the first connector, forming a first dielectric layer covering the first metal member on a surface of the first semiconductor substrate, and grinding the first dielectric layer to expose the first metal member; forming the second metal interconnection layer includes forming a second metal member on the second connection member, forming a second dielectric layer covering the second metal member on a surface of the second semiconductor substrate, and grinding the second dielectric layer to expose the second metal member.

Optionally, the first semiconductor substrate is a wafer, and the second semiconductor substrate is a wafer.

Optionally, a step of cutting the first semiconductor substrate or the second semiconductor substrate to form a chip is further included between forming the bonding member and performing the bonding step, and the bonding member is located at an edge of the chip.

Optionally, the uncut semiconductor substrate includes a TSV adapter plate.

Optionally, the first semiconductor substrate includes an HBM (high-bandwidth memory) TSV wafer, and the second semiconductor substrate includes an HBM TSV wafer.

Optionally, the method further includes grinding the HBM TSV wafer to expose the TSV and repeating the bonding step to prepare the HBM stack interconnection structure, where the number of layers of the stack includes N layers, and N is an integer and N≥2

According to the manufacturing method of the semiconductor interconnection structure of the present disclosure, a first metal interconnection layer electrically connected to a surface of the first semiconductor substrate is formed on a surface of the first semiconductor substrate, a bonding member is formed on an edge of the surface of at least one of the first metal interconnection layer and the second metal interconnection layer, and after the bonding process is performed, a metal interconnection member is formed by electroless plating to connect the first metal member and the second metal member in the first metal interconnection layer.

### BRIEF DESCRIPTION OF DRAWINGS

FIG. 1 is a process flow chart of a semiconductor interconnect structure according to the present invention.

FIG. 2 is a schematic top view of a wafer in Embodiment 1.

FIG. 3 is a cross-sectional view of FIG. 2.

FIG. 4 is a schematic structural diagram after a first metal interconnection layer is formed according to Embodiment 1.

FIG. 5 is a schematic structural diagram after grinding the first metal interconnection layer according to Embodiment 1.

FIG. 6 is a schematic top view of a structure formed after a bonding member is formed according to Embodiment 1.

FIG. 7 is a cross-sectional view of FIG. 6.

FIG. 8 is a schematic structural diagram after bonding according to Embodiment 1.

FIG. 9 is a schematic structural diagram after chemical plating according to Embodiment 1.

FIG. 10 is a schematic structural diagram after a bottom filling layer is formed according to Embodiment 1.

FIG. 11 is a schematic structural diagram of an HBM stack interconnection structure formed by layer 2 stacking according to Embodiment 2.

FIG. 12 is a schematic structural diagram after grinding and exposing TSVs according to Embodiment 2.

FIG. 13 is a schematic structural diagram of an HBM stack interconnection structure forming three layers of stacks according to Embodiment 2.

FIG. 14 is a schematic structural diagram of an HBM stack interconnection structure including four of stack layers according to Embodiment 2.

FIG. 15 is a schematic structural diagram of a semiconductor interconnection structure formed by a chip and a TSV adapter plate according to Embodiment 3.

FIG. 16 is a schematic structural diagram after forming a plastic package layer according to Embodiment 3.

FIG. 17 is a schematic structural diagram after forming a metal bump according to Embodiment 3.

FIG. 18 is a schematic structural diagram after bonding with a substrate to form a heat dissipation cover plate and a metal bump according to Embodiment 3.

### REFERENCE NUMERALS

| | |
|---|---|
| 100 | TSV |
| 101 | Chip |
| 111 | First connector |
| 110 | First semiconductor substrate |
| 120 | Second semiconductor substrate |
| 121 | Second connector |
| 210 | First metal interconnection layer |
| 211 | First metal member |
| 212 | First dielectric layer |
| 220 | Second metal interconnection layer |
| 221 | Second metal member |
| 222 | Second dielectric layer |
| 300 | Bonding member |
| 400 | Metal interconnection member |
| 500 | Bottom filling layer |
| 600 | Metal bump |
| 700 | Plastic encapsulation layer |
| 800 | Substrate |
| 900 | Heat dissipation cover plate |

### DETAILED DESCRIPTION

The embodiments of the present disclosure are described below through specific examples, and those skilled in the art can easily understand other advantages and effects of the present disclosure from the content disclosed in the present disclosure. The present disclosure may also be implemented or applied by different specific embodiments, and various details in this specification may also be modified or changed based on different viewpoints and applications without departing from the spirit of the present disclosure.

As described in detail in the embodiments of the present disclosure, for ease of description, a cross-sectional view of a device structure may not be locally enlarged according to a general proportion, and the schematic diagram is merely an example, which should not limit the protection scope of the present disclosure. In addition, a three-dimensional space size of length, width and depth should be included in actual manufacturing.

For ease of description, spatial relationship words such as “below”, “below”, “below”, “below”, “above”, and “upper” may be used herein to describe a relationship between one element or feature shown in the accompanying drawings and other elements or features. It will be understood that these spatial relationship words are intended to encompass other orientations of the device in use or operation in addition to the orientation depicted in the figures. Further, when a layer is referred to as being “between” two layers, it may be only a layer between the two layers, or one or more intervening layers may also be present. As used herein, “interposed”. The “representation comprises two endpoint values”.

In the context of this application, the structure of the first feature “above” the second feature may include an embodiment in which the first feature and the second feature are formed into direct contact, or may include an embodiment in which another feature is formed between the first feature and the second feature, so that the first feature and the second feature may not be in direct contact.

It should be noted that the drawings provided in this embodiment merely illustrate the basic idea of the present disclosure in a schematic way, only the components related to the present disclosure rather than the number, shape, and size of the components in actual implementation are shown in the tunnel diagram, and the configuration, quantity and proportion of the components in the actual implementation may be a random change, and the layout type of the components may also be more complex.

### Embodiment 1

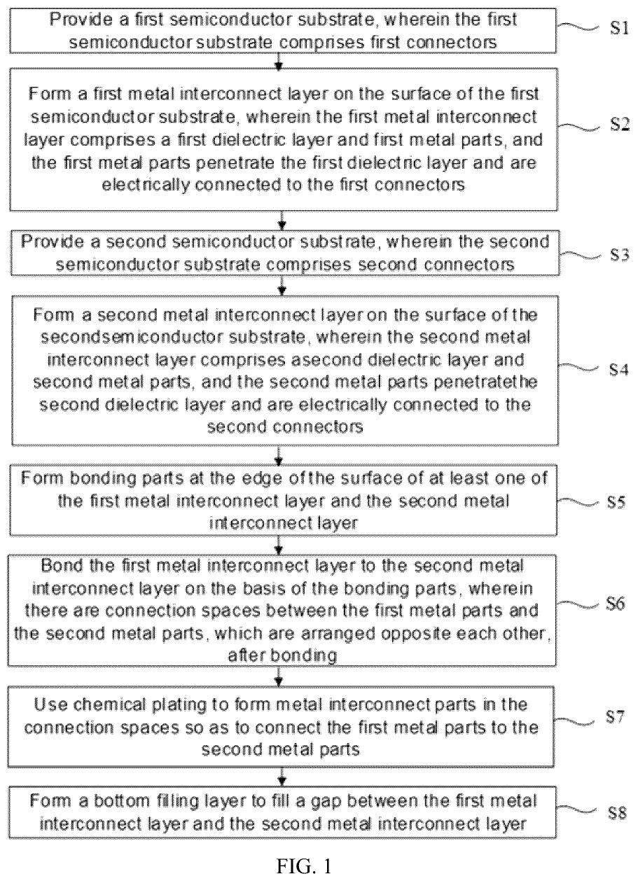

As shown in FIG. 1, this embodiment provides a method for manufacturing a semiconductor interconnection structure, including the following steps:
S 1: providing a first semiconductor substrate, the first semiconductor substrate comprising a first connector;
S 2: forming a first metal interconnection layer on a surface of the first semiconductor substrate, where the first metal interconnection layer includes a first dielectric layer and a first metal member, and the first metal member penetrates through the first dielectric layer and is electrically connected to the first connection member;
S 3: providing a second semiconductor substrate, the second semiconductor substrate comprising a second connector;
S 4: forming a second metal interconnection layer on a surface of the second semiconductor substrate, where the second metal interconnection layer includes a second dielectric layer and a second metal member, and the second metal member penetrates through the second dielectric layer and is electrically connected to the second connection member;
S 5: forming a bonding member on an edge of the surface of at least one of the first metal interconnection layer and the second metal interconnection layer;
S 6: bonding the first metal interconnection layer and the second metal interconnection layer based on the bonding member, and a connection space disposed opposite to the first metal member and the second metal member after bonding; and
S 7: forming a metal interconnection member at the connection space by electroless plating to connect the first metal member and the second metal member;
S 8: forming a bottom filling layer, and filling a gap between the first metal interconnection layer and the second metal interconnection layer.

According to the manufacturing method of the semiconductor interconnection structure of the embodiment, the first metal interconnection layer electrically connected is formed on the surface of the first semiconductor substrate, the second metal interconnection layer electrically connected is formed on the surface of the second semiconductor substrate, the bonding piece is formed on the edge of the surface of at least one of the first metal interconnection layer and the second metal interconnection layer, the connection space located between the first metal member and the second metal member is provided based on the bonding piece, and after the bonding process is performed, The first metal member and the second metal member can achieve good electrical interconnection by electroless plating, so that the first metal member and the second metal member have good flatness in the manufacturing process, and the cost required by the process is low, so that high-density integrated packaging can be performed, and semiconductor interconnection with high efficiency, low cost, easy process manufacturing process and wide application range is achieved.

As an example, the semiconductor interconnection structure includes an interconnection structure between a wafer and a wafer, or an interconnection structure between the chip and the wafer.

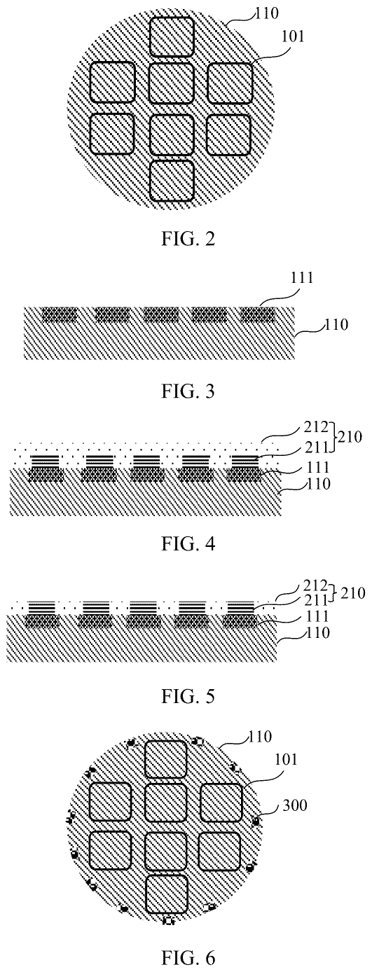

The following describes a semiconductor interconnection structure formed by interconnecting a wafer and a wafer with reference to FIG. 2 to FIG. 10, which may specifically include:

First, referring to FIG. 2 and FIG. 3, step S 1 is performed to provide a first semiconductor substrate 110, and the first semiconductor substrate 110 includes a first connector 111.

In this embodiment, the first semiconductor substrate 110 is a silicon wafer, but is not limited thereto, the size of the wafer may include, for example, 6 inches, 8 inches, 12 inches, etc. the wafer has a plurality of chips 101 distributed in an array, the type and size of the chip 101 are not limited herein, the front face of the chip 101 is provided with a bonding pad for electrical lead-out, and the bonding pad can be regarded as the first connector 111 of the first semiconductor substrate 110.

Next, referring to FIG. 4 and FIG. 5, step S 2 is performed to form a first metal interconnection layer 210 on a surface of the first semiconductor substrate 110, the first metal interconnection layer 210 includes a first dielectric layer 212 and a first metal member 211, and the first metal member 211 penetrates through the first dielectric layer 212 and is electrically connected to the first connector 111.

Specifically, the first metal member 211 may be a metal pillar, such as a copper pillar, an aluminum pillar, or the like, and the forming method may be performed by welding; the material of the first dielectric layer 212 may include an insulating material such as epoxy resin, and the forming method may be deposition, injection molding, and the like. The material and the forming method of the first metal member 211 and the first dielectric layer 212 are not excessively limited herein.

In this embodiment, the step of forming the first metal interconnection layer 210 may include sub-steps:
forming the first metal member 211 on the first connector 111;
forming a first dielectric layer 212 covering the first metal member 211 on a surface of the first semiconductor substrate 110; and
grinding the first dielectric layer 212 exposes the first metal member 211.

Thus, the first metal interconnect layer 210 having a flat surface may be formed.

Next, referring to FIG. 2 to FIG. 5 and FIG. 8, step S 3 is performed to provide a second semiconductor substrate 120, the second semiconductor substrate 120 includes a second connector 121, a second metal interconnect layer 220 is formed on a surface of the second semiconductor substrate 120, the second metal interconnect layer 220 includes a second dielectric layer 222 and a second metal member 221, and the second metal member 221 penetrates through the second dielectric layer 222 and is electrically connected to the second connector 121.

Specifically, in this embodiment, the second semiconductor substrate 120 adopts the same silicon wafer as the first semiconductor substrate 110, the second metal interconnection layer 220 and the first metal interconnection layer 210 can adopt the same material and structure to form the semiconductor interconnection structure of the wafer to the wafer, and the preparation of the second metal interconnection layer 220 is not repeated here, but the material, structure and preparation of the second semiconductor substrate 120 and the second metal interconnection layer 220 are not limited thereto.

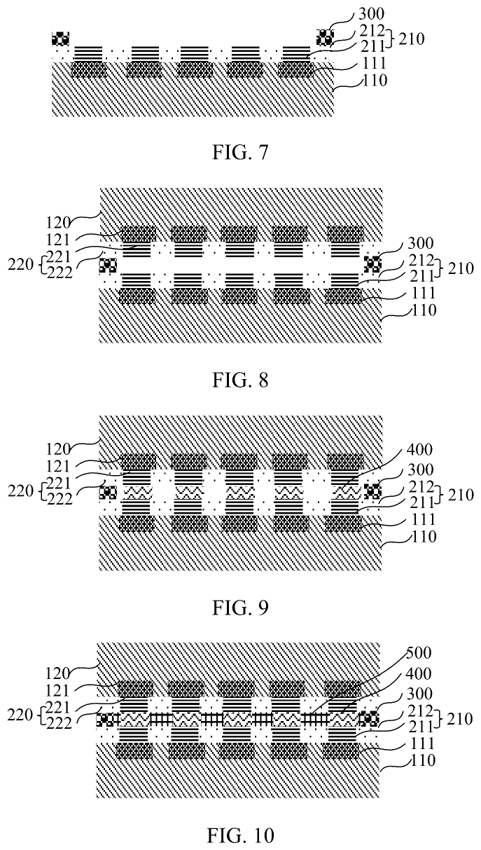

Next, referring to FIG. 6 and FIG. 7, step S 5 is performed to form a bonding member 300 on an edge of the surface of at least one of the first metal interconnection layer 210 and the second metal interconnection layer 220.

Specifically, in this embodiment, the bonding member 300 is formed on the edge of the surface of the first metal interconnection layer 210 on the first semiconductor substrate 110, wherein the first metal interconnection layer 210 is not shown in FIG. 6 because the first semiconductor substrate 110 and the second semiconductor substrate 120 are both wafer-level, so that the bonding member 300 can be formed on the premise of not occupying the effective area of the wafer, and the effective area of the wafer can be prevented from being occupied.

As an example, the bonding member 300 May include a thermosetting bonding member or a UV bonding member, a type of the bonding member 300 may be specifically selected as required, and the bonding member 300 May provide support for subsequent bonding of the first metal interconnection layer 210 and the second metal interconnection layer 220 to form a connection space, where the UV bonding member refers to an ultraviolet bonding member.

Next, referring to FIG. 8, step S 6 is performed, the first metal interconnection layer 210 and the second metal interconnection layer 220 are bonded based on the bonding member 300, and a connection space is left between the bonded first metal member 211 and the second metal member 221.

As an example, after the bonding, the perpendicular distance between the first metal interconnection layer 210 and the second metal interconnection layer 220 is in a range of 10 μm-50 μm.

Specifically, after bonding, a gap is formed between the first metal interconnection layer 210 and the second metal interconnection layer 220 based on the support of the bonding member 300, and the perpendicular distance between the first metal interconnection layer 210 and the second metal interconnection layer 220 may be in the range of 10 μm-50 μm, such as 10 μm, 20 μm, 30 μm, 40 μm, 50 μm, etc. and the bonding member 300 with a corresponding thickness may be prepared as required.

As an example, after the bonding, the center line of the first metal member 211 aligns with the center line of the second metal member 221.

Specifically, in this embodiment, since the first semiconductor substrate 110 has the same structure as the second semiconductor substrate 120, the first metal member 211 and the second metal member 221 have the same structure, and during bonding, the center line of the first metal member 211 aligns with the center line of the second metal member 221 by means of alignment, so that the connection space is left between the first metal member 211 and the second metal member 221, thereby facilitating the subsequent chemical plating process, but the position of the connection space between the first metal member 211 and the second metal member 221 is not limited thereto.

Next, referring to FIG. 9, step S 7 is performed to form a metal interconnect 400 at the connection space to connect the first metal member 211 and the second metal member 221.

Specifically, the material of the metal interconnection piece 400 may include the same material as the first metal member 211 and the second metal member 221, such as copper, silver, etc. so as to improve the bonding stability, and certainly, the metal interconnection piece 400 may also be made of a material different from that of the metal members, that is, electrical connection may be achieved, which is not excessively limited herein.

Next, referring to FIG. 10, step S 8 is performed to form a bottom filling layer 500 to fill a gap between the first metal interconnection layer 210 and the second metal interconnection layer 220, so that the metal interconnection element 400 is encapsulated and protected by the bottom filling layer 500, and the material of the bottom filling layer 500 is not excessively limited herein.

### Embodiment 2

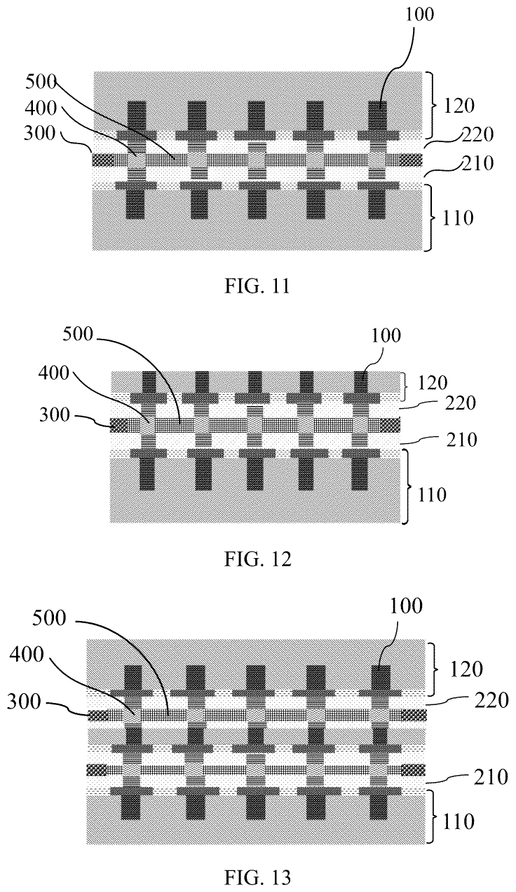

Referring to FIG. 11, the difference between this embodiment and the first embodiment mainly lies in that the first semiconductor substrate 110 adopts an HBM TSV wafer, the second semiconductor substrate 120 adopts an HBM TSV wafer, the HBM refers to a high-bandwidth memory, the structure of the HBM TSV wafer is not excessively limited herein, and the steps of forming the first metal interconnection layer 210, the second metal interconnection layer 220, the bonding member 300, the metal interconnection piece 400 and the bottom filling layer 500 may all refer to Embodiment 1, and details are not described herein again.

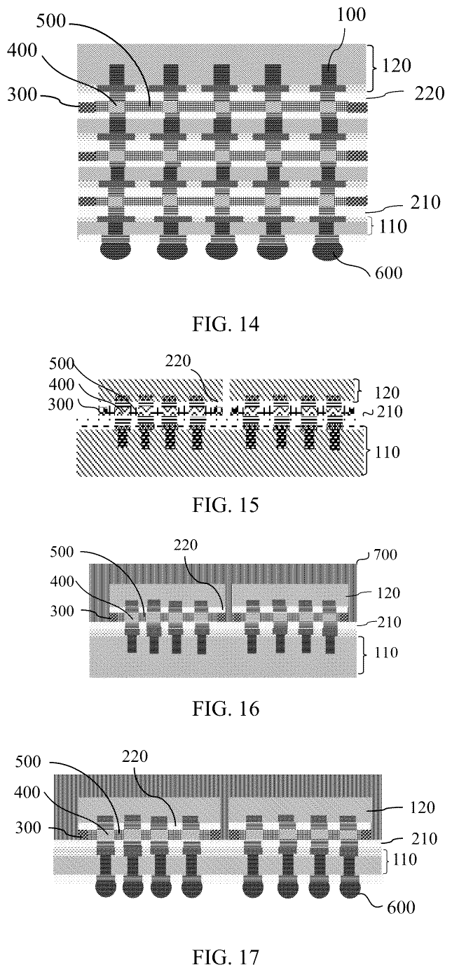

Further, referring to FIG. 12 to FIG. 14 (reference numerals for parts similar to previous figures are not included in these figures), the HBM TSV wafer may be grounded to expose the TSVs, and the bonding step may be repeated to prepare the HBM stack interconnection structure, where the number of layers of the stack may include N layers, N≥2, for example, N is an integer like 2, 3, 4, 5, etc. which is not excessively limited herein, where FIG. 11 illustrates a two layer HBM stack interconnection structure, and FIG. 13 illustrates a 3 layer HBM stack interconnection structure. FIG. 12 shows first grinding the second semiconductor substrate 120 to expose the TSV, followed by using the structure formed in FIG. 12 as the first semiconductor substrate 110. The exposed TSV is used as the first connector which is electrically connected in a way with reference to FIG. 11, that is, the second semiconductor substrate 120 is provided, and the steps of forming the first metal interconnect layer 210, the second metal interconnect layer 220, the bonding member 300, the metal interconnect 400, and the underfill layer 500 are repeated to prepare the three-layer HBM stack interconnect structure shown in FIG. 13, and FIG. 14 illustrates the preparation of the three layer HBM stack interconnect structure, and after the bonding is complete, the step of forming the metal bump 600 may also be included, as shown in FIG. 14, so as to perform subsequent electrical connection.

### Embodiment 3

Referring to FIG. 15 to FIG. 18 (reference numerals for parts similar to previous figures are not included in these figures), the difference between this embodiment and the first embodiment mainly lies in the step of cutting the first semiconductor substrate 110 or the second semiconductor substrate 120 to mount a chip, so as to form a semiconductor interconnection structure between the chip and the first semiconductor substrate 110 or the second semiconductor substrate 120 substrate whichever is cut. The bonding member 300 is located at an edge of the chip, and the uncut substrate may include a TSV adapter plate.

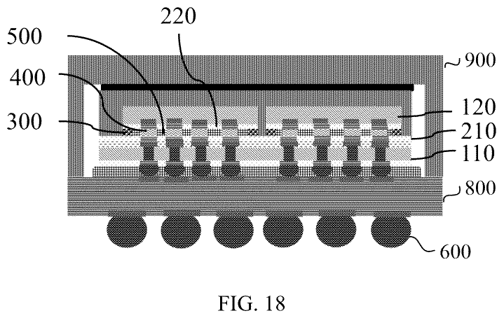

Specifically, with regard to the preparation of the second semiconductor substrate 120, the first metal interconnection layer 210, the second metal interconnection layer 220, the bonding member 300, the metal interconnection member 400 and the bottom filling layer 500 in FIG. 15, refer to Embodiment 1. After the semiconductor interconnection structure of FIG. 15 is complete, the steps of forming the plastic encapsulation layer 700, forming the metal bump 600 in FIG. 17, bonding with the substrate 800 in FIG. 18 to form the bottom filling layer 500, forming the metal bump 600, and the heat dissipation cover plate 900 in FIG. 16 may further include the steps of forming the bottom filling layer 500, forming the metal bumps 600, and the heat dissipation cover plate 900, which is not excessively limited herein.

In summary, according to the manufacturing method of the semiconductor interconnection structure of the present invention, the first metal interconnection layer electrically connected to the surface of the first semiconductor substrate is formed on the surface of the first semiconductor substrate, the bonding member is formed on the edge of the surface of at least one of the first metal interconnection layer and the second metal interconnection layer, and after the bonding process is performed, the first metal member 211 and the second metal member 221 are electrically interconnected in a chemical plating manner, so that the first metal member 211 and the second metal member 221 are flat during the manufacturing process, thus, the cost of manufacturing a high-density integrated packaging process becomes relatively low. As a result, a widely applicable semiconductor interconnection made with a high efficiency, low cost, and easy process is achieved.

The above embodiments are merely illustrative of the principles and effects of the present disclosure, and are not intended to limit the present disclosure. Any person skilled in the art may modify or change the above embodiments without departing from the spirit and scope of the present disclosure. Therefore, all equivalent modifications or changes made by a person of ordinary skill in the art without departing from the spirit and technical ideas disclosed in the present invention shall still be covered by the claims of the present invention.

1. A method for manufacturing a semiconductor interconnection structure, comprising following steps:
providing a first semiconductor substrate, wherein the first semiconductor substrate comprises a first connector;
forming a first metal interconnection layer on a surface of the first semiconductor substrate, where the first metal interconnection layer includes a first dielectric layer and a first metal member, and wherein the first metal member penetrates through the first dielectric layer and is electrically connected to the first connector;
providing a second semiconductor substrate, wherein the second semiconductor substrate comprises a second connector;
forming a second metal interconnection layer on a surface of the second semiconductor substrate, wherein the second metal interconnection layer includes a second dielectric layer and a second metal member, and wherein the second metal member penetrates through the second dielectric layer and is electrically connected to the second connector;
forming a bonding member on an edge of a surface of at least one of the first metal interconnection layer and the second metal interconnection layer;
bonding the first metal interconnection layer and the second metal interconnection layer with the bonding member, wherein a connection space is left between the first metal member and the second metal member after the bonding;
forming a metal interconnect at the connection space by electroless plating to connect the first metal member and the second metal member; and
forming a bottom filling layer, filling a gap between the first metal interconnection layer and the second metal interconnection layer.

2. The method for manufacturing the semiconductor interconnection structure according to claim 1, wherein after bonding the first metal interconnection layer and the second metal interconnection layer, a center line of the first metal member aligns with a center line of the second metal member.

3. The method for manufacturing the semiconductor interconnection structure according to claim 1, wherein after bonding the first metal interconnection layer and the second metal interconnection layer, a perpendicular distance between the first metal interconnection layer and the second metal interconnection layer is in the range of 10 μm-50 μm.

4. The method for manufacturing the semiconductor interconnection structure according to claim 1, wherein the bonding member comprises a thermosetting bonding member or a UV bonding member.

5. The method for manufacturing the semiconductor interconnection structure according to claim 1, wherein the step of forming the first metal interconnect layer includes forming the first metal member on the first connector, forming the first dielectric layer covering the first metal member on a surface of the first semiconductor substrate, and polishing the first dielectric layer to expose the first metal member; wherein forming the second metal interconnection layer includes forming a second metal member on the second connection member, forming the second dielectric layer covering the second metal member on a surface of the second semiconductor substrate, and polishing the second dielectric layer to expose the second metal member.

6. The method for manufacturing the semiconductor interconnection structure according to claim 1, wherein the first semiconductor substrate is a wafer, and the second semiconductor substrate is a wafer.

7. The method for manufacturing the semiconductor interconnection structure according to claim 6, further comprising a step of cutting the first semiconductor substrate or the second semiconductor substrate to mount a chip between the bonding member and the first semiconductor substrate or the second semiconductor substrate whichever is cut, wherein the bonding member is located at an edge of the chip.

8. The method for manufacturing the semiconductor interconnection structure according to claim 7, wherein the first semiconductor substrate or the second semiconductor substrate whichever is not cut comprises a TSV adapter plate.

9. The method for manufacturing the semiconductor interconnection structure according to claim 1, wherein the first semiconductor substrate comprises an HBM (high bandwidth memory) TSV wafer, and the second semiconductor substrate comprises an HBM TSV wafer.

10. The method for manufacturing the semiconductor interconnection structure according to claim 9, further comprising a step of polishing the HBM TSV wafer to expose the HBM TSV, and repeating the step of bonding the first metal interconnection layer and the second metal interconnection layer with the bonding member to prepare an N-layer stack of HBM interconnection structure, wherein N is an integer and N≥2.
